(19) United States
(12) Patent Application Publication
(10) Pub. No.: US 2026/0190557 A1
(43) Pub. Date: Jul. 2, 2026

(54) LIGHT EMITTING DIODE, ASSEMBLING SUBSTRATE FOR ASSEMBLING THEREOF AND DISPLAY DEVICE

(71) Applicant: LG Display Co., Ltd., Seoul (KR)

(72) Inventors: Sunghwan YOON, Seoul (KR); Jusang RIHM, Seoul (KR); RokHee LEE, Seoul (KR); Kanghyun KIM, Paju-si (KR)

(73) Assignee: LG Display Co., Ltd., Seoul (KR)

(21) Appl. No.: 19/383,410

(22) Filed: Nov. 7, 2025

(30) Foreign Application Priority Data
Dec. 31, 2024 (KR) 10-2024-0202756

(51) Int. Cl. H10H 20/857; H10H 20/831; H10H 29/39; H10H 29/49; H10H 29/85

(52) U.S. Cl. CPC H10H 20/857; H10H 20/831; H10H 29/39; H10H 29/49; H10H 29/8508

(57) ABSTRACT

A light emitting diode according includes a first semiconductor layer, a first electrode disposed on the first semiconductor layer, an emission layer disposed on the first semiconductor layer, a second semiconductor layer disposed on the emission layer, a second electrode disposed on the second semiconductor layer. A pattern is disposed below the first semiconductor layer and positioned to one side with respect to the center of the first semiconductor layer. The pattern is configured to interact with an electric field to enable controlled orientation and alignment of the light emitting diode during assembly. This structure allows the light emitting diode to be accurately positioned in a desired direction, improving assembly efficiency and reliability while maintaining stable electrical and optical performance in a display device.

### CROSS-REFERENCE TO RELATED APPLICATIONS

This application claims the priority of Korean Patent Application No. 10-2024-0202756 filed on Dec. 31, 2024, in the Korean Intellectual Property Office, the disclosure of which is incorporated herein by reference.

### BACKGROUND

### Technical Field

The present disclosure relates to a light emitting diode, an assembling substrate for assembling thereof, and a display device, and more particularly, to a light emitting diode which is self-aligned, an assembling substrate, and a display device.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

The present disclosure relates to a light emitting diode structure and an assembling substrate that allow automatic alignment and placement of light emitting diodes during manufacturing. Each light emitting diode includes first and second semiconductor layers, an emission layer, electrodes, and a pattern positioned asymmetrically below the first semiconductor layer. This pattern becomes dielectrically polarized under an electric field, allowing the light emitting diode to orient itself through dielectrophoresis so that it is accurately aligned without the need for manual positioning.

The assembling substrate includes first and second assembly electrodes of different lengths, creating an asymmetric electric field that interacts with the polarized pattern of the light emitting diode. This field driven alignment enables the light emitting diodes to be oriented correctly regardless of their initial position and allows different types of light emitting diodes, such as red, green, and blue devices with distinct permittivity or magnetic characteristics, to be selectively assembled at different voltages. As a result, various light emitting diodes can be positioned on a single substrate in a single process, simplifying assembly and reducing manufacturing time and cost.

By combining self aligning light emitting diodes with an assembling substrate optimized for dielectrophoretic alignment, the disclosed technology removes complex positioning steps, improves production yield, and allows all connection electrodes to be formed on a single layer. This approach provides a more efficient and scalable method of fabricating light emitting diode display panels that exhibit improved uniformity, stability, and overall production efficiency.

For example, various embodiments of the present disclosure provide a light emitting diode which is self-aligned and a display device comprising the light emitting diode.

Various embodiments of the present disclosure provide an assembling substrate which improves a production efficiency by reducing the number of processes by means of self-alignment of light emitting diodes.

Various embodiments of the present disclosure provide an assembling substrate which self-aligns light emitting diodes in a desired direction even though the light emitting diodes are mixed during the self-assembling.

Technical benefits of the present disclosure are not limited to the above-mentioned benefits, and other benefits, which are not mentioned above, can be clearly understood by those skilled in the art from the following descriptions.

A light emitting diode according to an aspect of the present disclosure comprises a first semiconductor layer, a first electrode disposed on the first semiconductor layer, an emission layer disposed on the first semiconductor layer, a second semiconductor layer disposed on the emission layer, a second electrode disposed on the second semiconductor layer, and a pattern which is disposed below the first semiconductor layer and is disposed at one side with respect to a center of the first semiconductor layer.

An assembling substrate according to an aspect of the present disclosure comprises a substrate, a first assembly line disposed on the substrate, a first assembly electrode which protrudes from one side of the first assembly line, a second assembly line disposed on the substrate, a second assembly electrode which protrudes from one side of the second assembly line and is disposed so as to face the first assembly electrode, and an organic layer which is disposed on the substrate and includes an opening, wherein a length of the first assembly electrode which protrudes from one side of the first assembly line is different from a length of the second assembly electrode which protrudes from one side of the second assembly line.

A display device according to an aspect of the present disclosure comprises a substrate, and a light emitting diode disposed on the substrate, wherein the light emitting diode includes a first semiconductor layer, a first electrode disposed on the first semiconductor layer, an emission layer disposed on the first semiconductor layer, a second semiconductor layer disposed on the emission layer, a second electrode disposed on the second semiconductor layer, and a pattern disposed below the first semiconductor layer and is disposed at one side with respect to a center of the first semiconductor layer.

Other detailed matters of the exemplary embodiments are included in the detailed description and the drawings.

According to the present disclosure, during the self-assembling, the self-alignment is possible to implement process optimization.

According to the present disclosure, during the self-assembling, light emitting diodes which emit light of various color are selectively assembled in one tray to reduce a manufacturing process and a manufacturing cost.

According to the present disclosure, during the self-assembling, various light emitting diodes are self-aligned in a desired direction to reduce a manufacturing process and a manufacturing cost.

According to the present disclosure, a plurality of connection electrodes connected to a light emitting diode are disposed on the same layer to reduce the manufacturing process.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a cross-sectional view illustrating an example of a cross-sectional shape of a light emitting diode according to an exemplary embodiment of the present disclosure;

FIG. 2 is a bottom view illustrating an example of a bottom surface of a light emitting diode according to an exemplary embodiment of the present disclosure;

FIG. 3 is a bottom view illustrating an example of a bottom surface of a light emitting diode according to another exemplary embodiment of the present disclosure;

FIG. 4 is a plan view of an assembling substrate according to an exemplary embodiment of the present disclosure;

FIG. 5 is an enlarged plan view of an assembly area of an assembling substrate according to an exemplary embodiment of the present disclosure;

FIG. 6 is an enlarged plan view of a unit area of an assembling substrate according to an exemplary embodiment of the present disclosure;

FIG. 7 is a cross-sectional view of an opening of an assembling substrate of a display device according to an exemplary embodiment of the present disclosure;

FIGS. 8A to 8F are process diagrams for explaining a manufacturing method of a display device according to an exemplary embodiment of the present disclosure;

FIG. 9 is an enlarged plan view of a unit area of an assembling substrate according to another exemplary embodiment of the present disclosure;

FIG. 10 is a schematic diagram of a display device according to an exemplary embodiment of the present disclosure; and

FIG. 11 is a cross-sectional view of a sub pixel of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When an element or layer is disposed “on” another element or layer, yet another element or layer may be interposed directly on the another element or layer or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the present disclosure.

As used herein, the term “external field” refers to any physical field capable of exerting a force or moment on the light emitting diode or on a component thereof, thereby influencing its position, orientation, or alignment. The external field may include, without limitation, an electric field, magnetic field, electromagnetic field, electrostatic field, or combinations thereof. In some embodiments, the external field may further include other types of force-generating environments such as gravitational, optical, acoustic, thermal, fluidic, or pressure-induced fields that can produce movement, rotation, or alignment of the light emitting diode. The nature, magnitude, or direction of the external field may be uniform or non-uniform, static or time-varying, and may be generated by electrodes, coils, radiation sources, temperature gradients, or any other suitable means. Unless otherwise specified, references to interaction with an external field are intended to encompass all such forms of physical field interaction capable of inducing translational or rotational motion of the light emitting diode.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

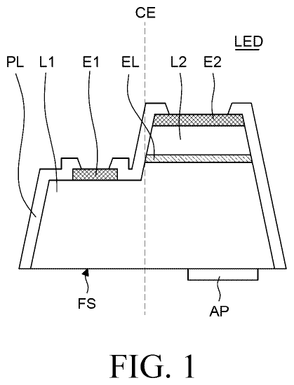

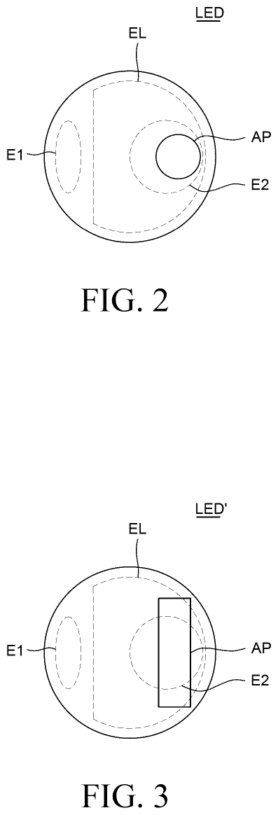

FIG. 1 is a cross-sectional view illustrating an example of a cross-sectional shape of a light emitting diode according to an exemplary embodiment of the present disclosure. FIG. 2 is a bottom view illustrating an example of a bottom surface of a light emitting diode according to an exemplary embodiment of the present disclosure.

Referring to FIGS. 1 and 2, a light emitting diode LED according to an exemplary embodiment of the present disclosure includes a first semiconductor layer L1, a first electrode E1 disposed on the first semiconductor layer L1, an emission layer EL disposed on the first semiconductor layer L1, a second semiconductor layer L2 disposed on the emission layer EL, a second electrode E2 disposed on the second semiconductor layer L2, and a pattern AP. The pattern AP is disposed below the first semiconductor layer L1 and is disposed at one side with respect to a center CE (see dotted line in FIG. 1) of the first semiconductor layer L1.

That is, the pattern disposed below the first semiconductor layer L1 may include a conductive, dielectric, or ferromagnetic material, or a combination thereof, and is positioned to one side with respect to the center CE of the light emitting diode LED. The pattern interacts with an external electric field or magnetic field to generate a force or torque that causes the light emitting diode LED to move or rotate in a direction. Through this interaction, the light emitting diode may be self-aligned during assembly without the need for mechanical adjustment. The pattern may also be referred to as an alignment structure, as it functions to align the light emitting diode by responding to electric, magnetic, or other external fields.

The first semiconductor layer L1 and the second semiconductor layer L2 may be layers formed by doping n-type or p-type impurities into a specific material, respectively. For example, the first semiconductor layer L1 may be an n-type semiconductor layer which is formed by doping an n-type impurity into a specific material and the second semiconductor layer L2 may be a p-type semiconductor layer formed by doping a p-type impurity into a specific material, but the present disclosure is not limited thereto.

Each of the first semiconductor layer L1 and the second semiconductor layer L2 may be a layer formed by doping an n-type or p-type impurity into a material, such as gallium nitride (GaN), indium aluminum phosphide (InAlP), or gallium arsenide (GaAs). In this case, the p-type impurity may be magnesium, zinc (Zn), beryllium (Be), and the like, and the n-type impurity may be silicon (Si), germanium, tin (Sn), and the like, but the present disclosure is not limited thereto.

The emission layer EL is disposed between the first semiconductor layer L1 and the second semiconductor layer L2. The emission layer EL is supplied with holes and electrons from the first semiconductor layer L1 and the second semiconductor layer L2 to emit light. The emission layer EL may be formed by a single layer or a multi-quantum well (MQW) structure, and for example, may be formed of indium gallium nitride (InGaN) or gallium nitride (GaN), but is not limited thereto.

The first electrode E1 is disposed on the first semiconductor layer L1. The first electrode E1 is an electrode which electrically connects a transistor and the first semiconductor layer L1. A planar shape of the first electrode E1 may be a bar shape extending in one direction, but is not limited thereto. The first semiconductor layer L1 may be a semiconductor layer doped with an n-type impurity and the first electrode E1 may be a cathode. The first electrode E1 may be disposed on a top surface of the first semiconductor layer L1 which is exposed from the emission layer EL and the second semiconductor layer L2. The first electrode E1 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode E2 is disposed on the second semiconductor layer L2. The second electrode E2 may be disposed on the top surface of the second semiconductor layer L2. The second electrode E2 may be an electrode for electrically connecting a power line and the second semiconductor layer L2. In this case, the second semiconductor layer L2 may be a semiconductor layer doped with a p-type impurity and the second electrode E2 may be an anode. The second electrode E2 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

An encapsulation film PL which encloses the first semiconductor layer L1, the emission layer EL, and the second semiconductor layer L2 is disposed. The encapsulation film PL is formed of an insulating material to protect the first semiconductor layer L1, the emission layer EL, and the second semiconductor layer L2. In the first encapsulation film PL, a contact hole which exposes the first electrode E1 and the second electrode E2 is formed. Therefore, a part of a top surface of each of the first electrode E1 and the second electrode E2 may be exposed. The first electrode E1 and the second electrode E2 may be electrically connected to the transistor and the power line, respectively, through a plurality of connection lines connected to the exposed top surfaces.

The pattern AP is disposed on a bottom surface of the first semiconductor layer L1. The pattern AP is disposed to be biased toward one side with respect to the center CE of the first semiconductor layer L1 on the bottom surface of the first semiconductor layer L1. For example, on a plane (for example, a projection plane), the first electrode E1 and the second electrode E2 may be disposed on different sides. In this case, one side on which the pattern AP is biased on the bottom surface of the first semiconductor layer L1 may be one side at which the second electrode E2 is disposed. Specifically, when the first electrode E1 is disposed at one side with respect to the center CE of the first semiconductor layer L1 on the plane, the second electrode E2 may be disposed on the other side with respect to the center CE of the first semiconductor layer L1. In this case, the pattern AP may be disposed to be biased to one side at which the second electrode E2 is disposed on the bottom surface of the first semiconductor layer L1. Therefore, the pattern AP may be disposed so as to overlap the second electrode E2. In contrast, the pattern AP may be disposed so as not to overlap the first electrode E1. The second electrode E2 may overlap the emission layer EL. In this case, the pattern AP may overlap the emission layer EL.

A planar shape of the pattern AP may be a circle. In this case, an area of the pattern AP on the plane may be smaller than an area of the second electrode E2, but is not limited thereto.

The pattern AP may include a metal material. For example, the pattern AP may include one or more of titanium dioxide (TiO₂), indium tin oxide (ITO), gold (Au), silver (Ag), aluminum (Al), and chromium (Cr). The pattern AP may include a ferromagnetic material, but is not limited thereto.

In the meantime, if the first electrode and the second electrode of the light emitting diode are disposed on opposite sides, when the light emitting diode is self-assembled, the first electrode and the second electrode of the light emitting diode may be randomly located. As described above, when the light emitting diode is self-assembled, it is difficult to place the first electrode and the second electrode as intended.

Therefore, the light emitting diode LED according to the exemplary embodiment of the present disclosure includes a pattern AP on a bottom surface. In this case, the pattern AP is dielectrically polarized by an electric field which is formed at an assembly electrode of an assembling substrate used for the self-assembling of the light emitting diode LED to have a polarity. The dielectrically polarized light emitting diode LED may move or may be fixed in a specific direction by dielectrophoresis (DEP), that is, by an electric field.

In the light emitting diode LED according to the exemplary embodiment of the present disclosure, the dielectrically polarized pattern AP is disposed to be biased to one side of the bottom surface of the light emitting diode LED. Therefore, the light emitting diode LED according to the exemplary embodiment of the present disclosure may change a direction in which the light emitting diode LED is disposed by adjusting a position or a shape of the assembly electrode of the assembling substrate used for the self-assembling. Accordingly, the light emitting diode LED according to the exemplary embodiment of the present disclosure may be self-aligned in a direction intended by a user during the self-assembling.

FIG. 3 is a bottom view illustrating an example of a bottom surface of a light emitting diode according to another exemplary embodiment of the present disclosure.

Referring to FIG. 3, a light emitting diode LED′ according to another exemplary embodiment of the present disclosure has substantially the same configurations as the light emitting diode LED of FIGS. 1 and 2, except for a planar shape of the pattern AP, so that a redundant description will be omitted.

Referring to FIG. 3, a planar shape of the pattern AP of the light emitting diode LED′ according to another exemplary embodiment of the present disclosure may be a rectangle. Therefore, the pattern AP may include a long side extending in one direction on a plane. In this case, when the first electrode E1 has an oval shape including a major axis extending in one direction, the long side of the pattern AP may be disposed to be parallel to the major axis of the first electrode E1.

On the plane, the pattern AP may be disposed at an opposite side of the first electrode E1. The pattern AP may be disposed to be spaced apart from the first electrode E1 so as not to overlap the first electrode E1. Specifically, when the first electrode E1 may be disposed at one side with respect to the center CE of the first semiconductor layer L1 on the plane, the second electrode E2 may be disposed on the other side with respect to the center CE of the first semiconductor layer L1.

The pattern AP may be disposed so as to overlap the second electrode E2. The second electrode E2 may overlap the emission layer EL. Therefore, the pattern AP may overlap the emission layer EL in a plan view.

The pattern AP may include a metal material. For example, the pattern AP may include one or more of titanium dioxide (TiO₂), indium tin oxide (ITO), gold (Au), silver (Ag), aluminum (Al), and chromium (Cr).

The light emitting diode LED′ according to another exemplary embodiment of the present disclosure includes a pattern AP which is biased to one side on the bottom surface to adjust the light emitting diode LED′ to be disposed in an intended direction during the self-assembling. Accordingly, the light emitting diode LED′ according to another exemplary embodiment of the present disclosure may be self-aligned in a direction intended by a user during the self-assembling.

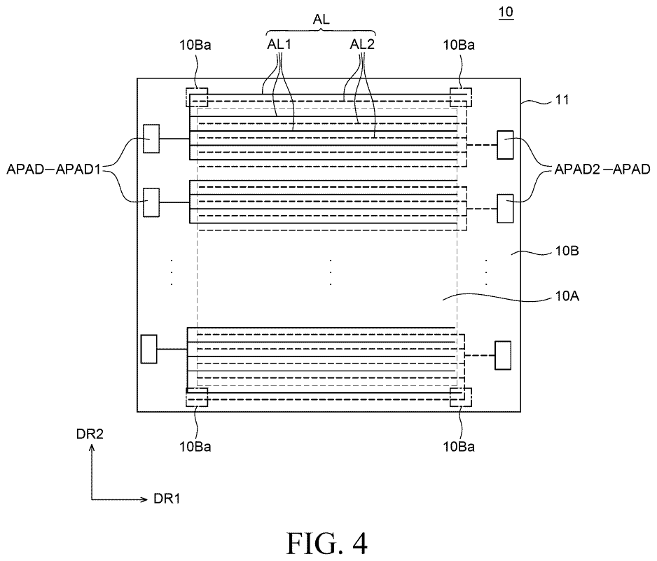

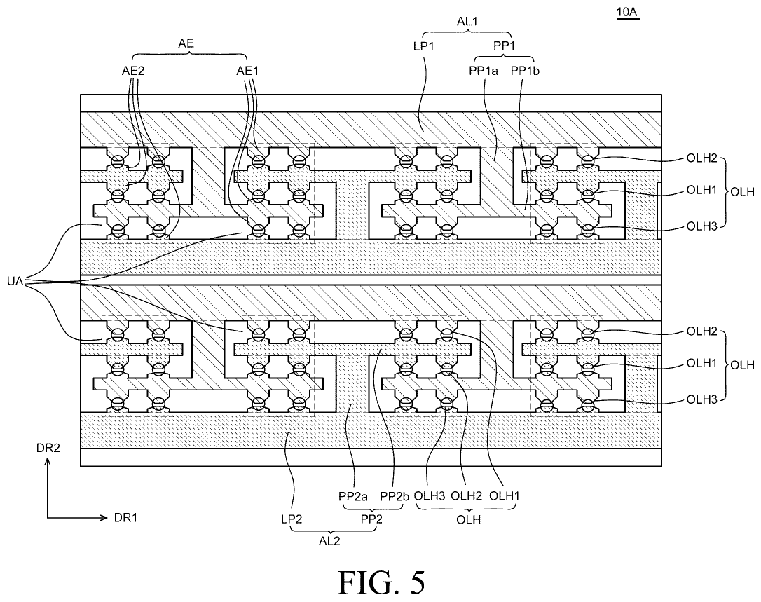

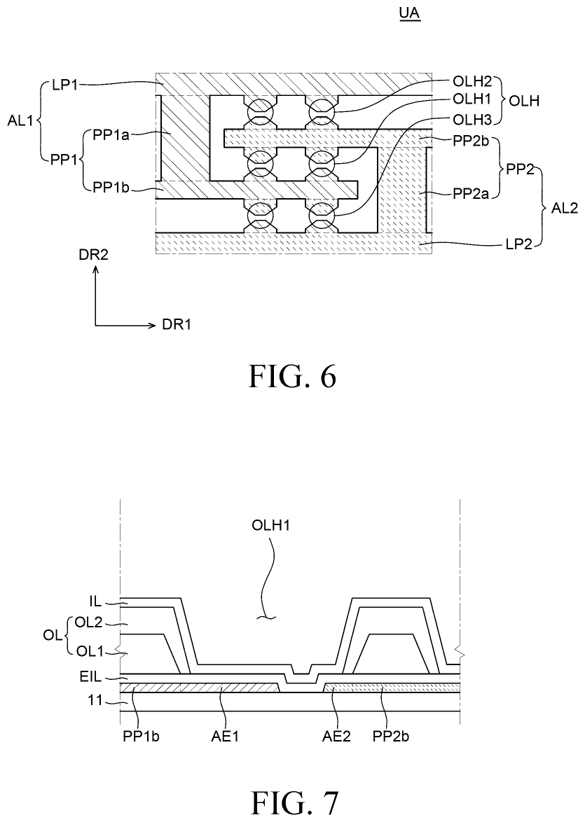

FIG. 4 is a plan view of an assembling substrate according to an exemplary embodiment of the present disclosure. FIG. 5 is an enlarged plan view of an assembly area of an assembling substrate according to an exemplary embodiment of the present disclosure. FIG. 6 is an enlarged plan view of a unit area of an assembling substrate according to an exemplary embodiment of the present disclosure. FIG. 7 is a cross-sectional view of an opening of an assembling substrate of a display device according to an exemplary embodiment of the present disclosure.

Referring to FIGS. 4 and 5, the assembling substrate 10 includes an assembly area 10A and an outer peripheral area 10B. The assembly area 10A is an area in which a plurality of light emitting diodes are self-assembled and a plurality of assembly lines AL and a plurality of assembly electrodes AE for self-assembling the light emitting diode are disposed. The outer peripheral area 10B is a remaining area excluding the assembly area 10A and a plurality of assembly pads and a plurality of alignment keys may be disposed therein.

Referring to FIGS. 4 to 7, the assembling substrate 10 may include a substrate 11, a plurality of assembly lines AL, a plurality of assembly electrodes AE, a plurality of assembly pads APAD, an organic layer OL, an electrode insulating layer EIL, and an assembly insulating layer IL.

First, referring to FIGS. 5 to 7, in the assembly area 10A, the plurality of assembly lines AL and the plurality of assembly electrodes AE are disposed on the substrate 11.

The plurality of assembly lines AL includes a plurality of first assembly lines AL1 and a plurality of second assembly lines AL2. The plurality of first assembly lines AL1 and the plurality of second assembly lines AL2 may be disposed to be spaced apart from each other with a predetermined interval. The plurality of first assembly lines AL1 and the plurality of second assembly lines AL2 may be alternately disposed. The plurality of first assembly lines AL1 and the plurality of second assembly lines AL2 are applied with different voltages so that an electric field may be formed between the plurality of first assembly lines AL1 and the plurality of second assembly lines AL2. The plurality of light emitting diodes LED may be self-assembled between the plurality of first assembly lines AL1 and the plurality of second assembly lines AL2 using the electric field formed between the plurality of first assembly lines AL1 and the plurality of second assembly lines AL2.

Each of the plurality of first assembly lines AL1 includes a first line parts LP1 and a plurality of first protrusion parts PP1. The first line part LP1 is a part which straightly extends from the assembly area 10A along a first direction DR1. The first line part LP1 extends from the assembly area 10A to the outer peripheral area 10B and may be electrically connected to the plurality of assembly pads of the outer peripheral area 10B.

The plurality of first protrusion parts PP1 is connected to one first line part LP1. The plurality of first protrusion parts PP1 may extend from one side surface of the first line part LP1 toward a second assembly line AL2 adjacent thereto. The plurality of first protrusion parts PP1 may be disposed to self-assemble a plurality of first light emitting diodes, a plurality of second light emitting diodes, and a plurality of third light emitting diodes between one first assembly line AL1 and one second assembly line AL2 which are adjacent to each other. The plurality of first protrusion parts PP1 is disposed to be alternate with a plurality of second protrusion parts PP2 of the second assembly line AL2 to be described below and may forms a plurality of electric fields to self-assemble the light emitting diode LED so as to correspond to a plurality of first sub pixels, a plurality of second sub pixels, and a plurality of third sub pixels. Accordingly, the plurality of first protrusion parts PP1 is disposed between an area between the first assembly line AL1 and the second assembly line AL2 to self-assemble the first light emitting diode, the second light emitting diode, and the third light emitting diode with an interval between a plurality of sub pixels.

Accordingly, in order to self-assemble all the first light emitting diodes, the second light emitting diodes, and the third light emitting diodes between one first assembly line AL1 and one second assembly line AL2 which are adjacent to each other, the plurality of first protrusion parts PP1 may be connected to one first line part LP1. Therefore, the plurality of first light emitting diodes, the plurality of second light emitting diodes, and the plurality of third light emitting diodes are self-assembled using the same assembly line AL to ensure a design area of the plurality of assembly line AL. Further, during a process of forming the assembly line AL so as to correspond to the interval between the sub pixels, a width of the assembly line AL may be ensured and the increase of resistance is suppressed to suppress the deterioration of an assembly rate.

Each of the plurality of first protrusion parts PP1 includes a first part PP1a and a second part PP1b. The first part PP1a is a part extending from the first line part LP1 in a second direction DR2. The first part PP1a may be a connection member for transmitting a voltage to the second part PP1b. One end of the first part PP1a may be connected to the first line part LP1 and the other end of the first part PP1a may be connected to the second part PP1b.

The second part PP1b is connected to the other end of the first part PP1a and extends in the first direction DR1. The second part PP1b may be alternately disposed with the second protrusion part PP2 of the second assembly line AL2 while extending in the first direction DR1. The second part PP1b may be disposed in an area between a fourth part PP2b of the second protrusion part PP2 of the second assembly line AL2 and the second line part LP2. The second part PP1b is disposed to be adjacent to the fourth part PP2b of the second protrusion part PP2 and the second line part LP2 to form an electric field to self-assemble the plurality of first light emitting diodes, the plurality of second light emitting diodes, and the plurality of third light emitting diodes.

Each of the plurality of second assembly lines AL2 includes a second line part LP2 and a plurality of second protrusion parts PP2. The second line part LP2 is a part which straightly extends from the assembly area 10A along a first direction DR1. In the second direction DR2, the second line part LP2 may be disposed alternately with the first line part LP1. The second line part LP2 extends from the assembly area 10A to the outer peripheral area 10B and may be electrically connected to the plurality of assembly pads of the outer peripheral area 10B.

The plurality of second protrusion parts PP2 are connected to the second line part LP2. The plurality of second protrusion parts PP2 may extend from the other side surface of the second line part LP2 in the second direction DR2. Each of the plurality of second protrusion parts PP2 includes a third part PP2a and a fourth part PP2b. The third part PP2a is a part extending from the second line part LP2 in the second direction DR2. The third part PP2a may be a connection member for transmitting a voltage to the fourth part PP2b. One end of the third part PP2a may be connected to the second line part LP2 and the other end of the third part PP2a may be connected to the fourth part PP2b. The third part PP2a may be disposed alternately with the first part PP1a of the first assembly line AL1 adjacent thereto. Accordingly, the third part PP2a and the first part PP1a are alternately disposed so that the fourth part PP2b connected to the third part PP2a may be disposed alternately with the second part PP1b connected to the first part PP1a.

The fourth part PP2b is connected to the other end of the third part PP2a and extends in the first direction DR1. The fourth part PP2b extends in the first direction DR1 and may be alternately disposed with the second part PP1b of the first protrusion part PP1 of the first assembly line AL1. The fourth part PP2b may be disposed in an area between the second part PP1b of the first protrusion part PP1 of the first assembly line AL1 and the first line part LP1. In the second direction DR2, the fourth part PP2b of the second assembly line AL2 and the second part PP1b of the first assembly line AL1 may face each other. Accordingly, the fourth part PP2b of the second assembly line AL2 may form an electric field to self-assemble the plurality of first light emitting diodes, the plurality of second light emitting diodes, and the plurality of third light emitting diodes together with the first line part LP1 and the second part PP1b of the first assembly line AL1 adjacent thereto.

The plurality of assembly electrodes AE includes a plurality of first assembly electrodes AE1 and a plurality of second assembly electrodes AE2. The plurality of first assembly electrodes AE1 may be connected to the plurality of first assembly lines AL1 and the plurality of second assembly electrodes AE2 may be connected to the plurality of second assembly lines AL2. One pair of first assembly electrode AE1 and second assembly electrode AE2 are disposed to be adjacent to each other to form an electric field to self-assemble the light emitting diode. Each of one pair of first assembly electrode AE1 and second assembly electrode AE2 may be disposed to correspond to a correct position in which the light emitting diode is transferred in the plurality of sub pixels.

Some of the plurality of first assembly electrodes AE1 may be disposed to protrude from one side surface of the first line part LP1 in the second direction DR2. The other part of the plurality of first assembly electrodes AE1 may be disposed to protrude from both side surfaces of the second part PP1b of the first protrusion part PP1 in the second direction DR2. For example, four first assembly electrodes AE1 may be connected to each of both side surfaces of one second part PP1b.

Each of the plurality of first assembly electrodes AE1 may include a part which is narrowed in the second direction DR2. For example, in any one first assembly electrode AE1, at least a partial area may be narrowed toward the end thereof. The end of the first assembly electrode AE1 may be parallel to the first assembly line LP1. Therefore, an end which protrudes from the first assembly electrode AE1 in the second direction DR2 may be narrower than the opposite end thereof.

Some of the plurality of second assembly electrodes AE2 may be disposed to protrude from the other side surface of the second line part LP2 in the second direction DR2. Some second assembly electrodes AE2 connected to the second line part LP2 may face the first assembly electrode AE1 which protrudes from the second part PP1b of the first assembly line AL1 adjacent thereto. Some of the plurality of second assembly electrodes AE1 may be disposed to protrude from both side surfaces of the fourth part PP2b of the second protrusion part PP2 in the second direction DR2. Among them, the second assembly electrode AE2 protruding from one side surface of the fourth part PP2b may face the first assembly electrode AE1 which protrudes from the other side surface of the second part PP1b of the first assembly line AL1 adjacent thereto. The second assembly electrode AE2 protruding from the other side surface of the fourth part PP2b may face the first assembly electrode AE1 which protrudes from the first line part LP1 of the first assembly line AL1 adjacent thereto.

The plurality of second assembly electrodes AE2 may include a part which is narrowed in the second direction DR2. For example, in any one second assembly electrode AE2, at least a partial area may be narrowed toward the end thereof. The end of the second assembly electrode AE2 may be parallel to the second assembly line LP2. Therefore, an end which protrudes from the second assembly electrode AE2 in the second direction DR2 may be narrower than the opposite end thereof.

A length of the plurality of first assembly electrodes AE1 protruding from the first assembly line AL1 and the first part PP1a is different from a length of the plurality of second assembly electrodes AE2 protruding from the second assembly line AL2 and the fourth part PP2b. For example, the length of the plurality of first assembly electrodes AE1 protruding from the first assembly line AL1 and the first part PP1a may be longer than the length of the plurality of second assembly electrodes AE2 protruding from the second assembly line AL2 and the fourth part PP2b.

Ends of the plurality of first assembly electrodes AE1 and the plurality of second assembly electrodes AE2 may face each other. In the present disclosure, the end of the first assembly electrode AE1 refers to an end portion of the first assembly electrode AE1 which is the furthest from the first line AL1 and the first part PP1a. The end of the second assembly electrode AE2 refers to an end portion of the second assembly electrode AE2 which is the furthest from the second line AL2 and the fourth part PP2b.

Ends of the plurality of first assembly electrodes AE1 and ends of the plurality of second assembly electrodes AE2 may be parallel to each other. A width of the ends of the plurality of first assembly electrodes AE1 and a width of the ends of the plurality of second assembly electrodes AE2 may be the same, but the present disclosure is not limited thereto.

On an area in which the first assembly electrode AE1 and the second assembly electrode AE2 which face each other are spaced apart from each other, any one of the first light emitting diode, the second light emitting diode, and the third light emitting diode may be self-assembled with an interval and an arrangement corresponding to each of the plurality of sub pixels. For example, the first light emitting diode may be self-assembled on an area in which the first assembly electrode AE1 of the first line part LP1 and the second assembly electrode AE2 of the fourth part PP2b which face each other are spaced apart from each other. The second light emitting diode may be self-assembled on an area in which the first assembly electrode AE1 of the second part PP1b and the second assembly electrode AE2 of the fourth part PP2b which face each other are spaced apart from each other. The third light emitting diode may be self-assembled on an area in which the first assembly electrode AE1 of the second part PP1b and the second assembly electrode AE2 of the second line part LP2 which face each other are spaced apart from each other.

Accordingly, the plurality of first protrusion parts PP1 and the plurality of second protrusion parts PP2 are alternately disposed between one first assembly line AL1 and the second assembly line AL2 which are adjacent to each other. By doing this, the first light emitting diode of the first sub pixel, the second light emitting diode of the second sub pixel, and the third light emitting diode of the third sub pixel may be self-assembled at one time.

Referring to FIG. 4, a plurality of assembly pads APAD are disposed on the assembling substrate 10 in the outer peripheral area 10B. The plurality of assembly pads APAD include a plurality of first assembly pads APAD1 and a plurality of second assembly pads APAD2. The plurality of first assembly lines AL1 and the plurality of first assembly electrodes AE1 are connected to the plurality of first assembly pads APAD1 to be applied with a voltage. The plurality of second assembly lines AL2 and the plurality of second assembly electrodes AE2 are connected to the plurality of second assembly pads APAD2 to be applied with a voltage. Some first assembly lines AL1 among the plurality of first assembly lines AL1 may be connected to one first assembly pad APAD1 and some second assembly lines AL2 among the plurality of second assembly lines AL2 may be connected to one second assembly pad APAD2.

Referring to FIG. 7, the electrode insulating layer EIL is disposed on the plurality of assembly lines AL and the plurality of assembly electrodes AE. The electrode insulating layer EIL protects the plurality of assembly lines AL and the plurality of assembly electrodes AE from a fluid to suppress a defect such as corrosion of the plurality of assembly lines AL and the plurality of assembly electrodes AE. The electrode insulating layer EIL may be configured by oxide or nitride, and for example, configured by a single layer or a double layer of silicon oxide (SiOx) or silicon nitride (SiNx), but is not limited thereto.

Next, referring to FIGS. 6 and 7 together, an organic layer OL including a plurality of openings OLH is disposed on the electrode insulating layer EIL.

The organic layer OL may include a first organic layer OL1 and a second organic layer OL2. The first organic layer OL1 may be disposed on the plurality of assembly lines AL and the second organic layer OL2 may be disposed on the first organic layer OL1. A thickness of the organic layer OL which can be formed by one process may be limited. If the thickness of the organic layer OL is equal to or smaller than a predetermined level, the light emitting diode which is self-assembled in the opening OLH of the organic layer OL may not be properly seated in the opening OLH. In contrast, when the thickness of the organic layer OL is excessively thick, it is difficult to attach the light emitting diode which is self-assembled in the opening OLH of the organic layer OL to a donor.

Therefore, the thickness of the organic layer OL may be adjusted by forming a plurality of organic layers OL. The organic layer OL may at least have a thickness smaller than a height of the light emitting diode. Even though in FIG. 7, it is illustrated that the organic layer OL includes a first organic layer OL1 and a second organic layer OL2, the organic layer OL may be formed as a single layer or further include an additional organic layer OL, in addition to the first organic layer OL1 and the second organic layer OL2. However, the organic layer is not limited thereto.

The organic layer OL may include a plurality of openings OLH. Each of the plurality of openings OLH which is formed by opening a part of the organic layer OL is an area in which the plurality of light emitting diodes are self-assembled. The plurality of openings OLH may be disposed so as to overlap an area in which the first assembly electrode AE1 and the second assembly electrode AE2 are spaced apart from each other. In this case, the protruding lengths of the first assembly electrode AE1 and the second assembly electrode AE2 are different from each other. Therefore, the area in which the first assembly electrode AE1 and the second assembly electrode AE2 are spaced apart from each other may be disposed to be biased to one side with respect to the center of the opening OLH which overlaps them. For example, the area in which the first assembly electrode AE1 and the second assembly electrode AE2 are spaced apart from each other may be disposed to be biased toward the second assembly electrode AE2 with respect to the center of the opening OLH.

The plurality of openings OLH may be disposed so as to overlap the plurality of first assembly electrodes AE1 and the plurality of second assembly electrodes AE2. In this case, a size of an area in which the plurality of first assembly electrodes AE1 and the plurality of openings OLH overlap and a size of an area in which the plurality of second assembly electrodes AE2 and the plurality of openings OLH overlap may be different from each other. For example, the size of the area in which the plurality of first assembly electrodes AE1 and the plurality of openings OLH overlap may be larger than the size of the area in which the plurality of second assembly electrodes AE2 and the plurality of openings OLH overlap.

The plurality of openings OLH may include a plurality of first openings OLH1, a plurality of second openings OLH2, and a plurality of third openings OLH3.

Referring to FIG. 6, one pair of first openings OLH1, one pair of second openings OLH2, and one pair of third openings OHL3 may form a unit area UA. The unit area UA is an area corresponding to one pixel and may be formed in a position corresponding to each of a plurality of pixels of a display device. Each unit area UA may be disposed to correspond to the pixels one to one and the light emitting diode which is self-assembled in each unit area UA may be transferred to each of the plurality of pixels.

For example, each of the plurality of first openings OLH1, the plurality of second openings OLH2, and the plurality of third openings OLH3 may be disposed so as to correspond to a plurality of first sub pixels, a plurality of second sub pixels, and a plurality of third sub pixels. Accordingly, the light emitting diode which is self-assembled in the plurality of openings OLH may be transferred to the plurality of sub pixels as it is.

In the meantime, referring to FIG. 6, in one unit area UA, the second opening OLH2, the first opening OLH1, and the third opening OLH3 may be sequentially disposed. For example, the second opening OLH2, the first opening OLH1, and the third opening OLH3 may be sequentially disposed along the second direction DR2 between the first assembly line AL1 and the second assembly line AL2 which are adjacent to each other.

Referring to FIG. 7, the assembly insulating layer IL may be disposed on the organic layer OL. The assembly insulating layer IL protects the plurality of assembly lines AL, the plurality of assembly electrodes AE, and the organic layer OL from the fluid to suppress the defect such as corrosion of the plurality of assembly lines AL.

Referring to FIG. 4, the outer peripheral area 10B includes one or more first alignment areas 10Ba. For example, a plurality of first alignment areas 10Ba may be formed to be adjacent to four corners of the assembly area 10A, respectively.

In the first alignment area 10Ba, an assembly line AL and an assembly electrode AE may be further disposed on the assembling substrate 10.

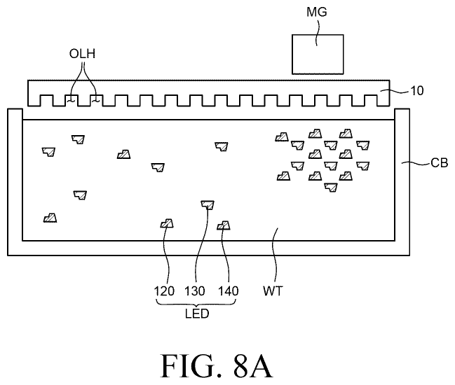

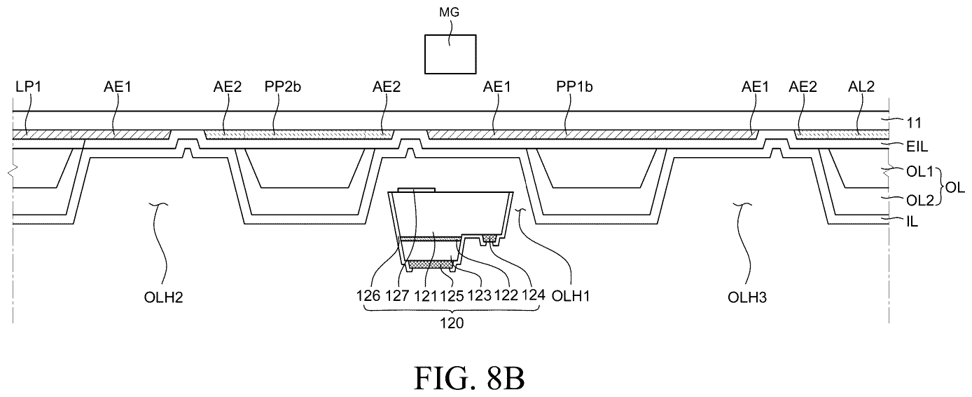

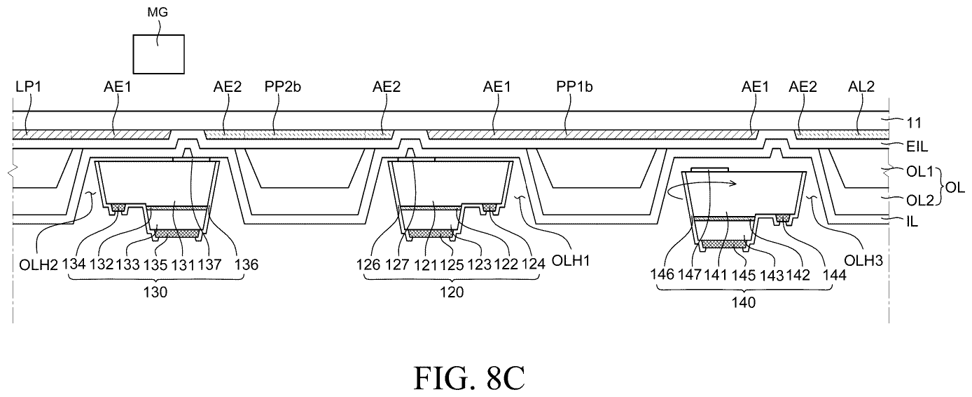

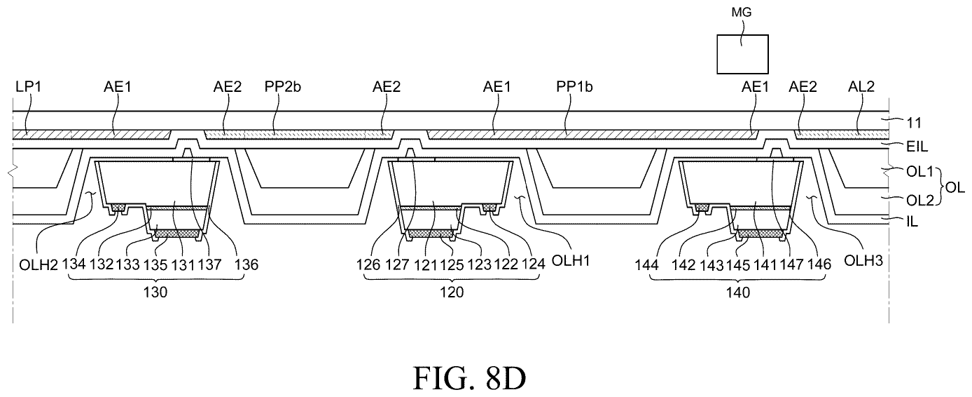

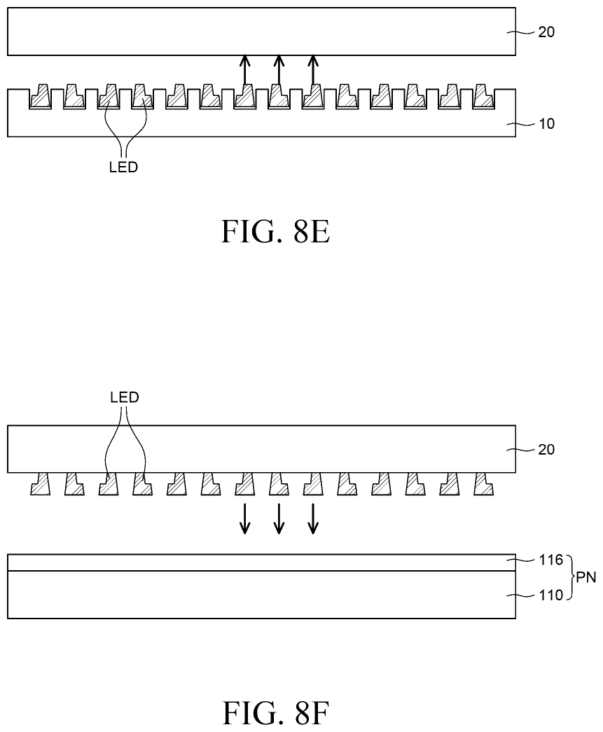

Hereinafter, a display device 100 according to an exemplary embodiment of the present disclosure using an assembling substrate 10 according to an exemplary embodiment of the present disclosure will be described with reference to FIGS. 8A to 8F.

FIGS. 8A to 8F are process diagrams for explaining a manufacturing method of a display device according to an exemplary embodiment of the present disclosure.

Specifically, FIGS. 8A and 8D are diagrams for explaining a process of self-assembling a light emitting diode LED on an assembling substrate 10. FIG. 8E is a diagram for explaining a process of transferring the light emitting diode LED on the assembling substrate 10 to a donor 20. FIG. 8F is a diagram for explaining a process of transferring the light emitting diode LED on the donor 20 to a display panel PN.

Referring to FIG. 8A, a plurality of light emitting diodes LED are self-assembled on the assembling substrate 10.

First, the light emitting diode LED which is grown on a wafer is put into a chamber CB filled with a fluid WT. The fluid WT may include water and a top of the chamber CB filled with fluid WT may be open.

In this case, the plurality of light emitting diodes LED is light emitting diodes LED according to the exemplary embodiment of the present disclosure. The plurality of light emitting diodes LED may include a plurality of first light emitting diodes 120, a plurality of second light emitting diodes 130, and a plurality of third light emitting diodes 140 which emit light of different color.

Each of the plurality of light emitting diodes LED may be formed on different wafers according to emission wavelength bands. For example, when the first light emitting diode 120 emits light in a red wavelength band, the first light emitting diode 120 may be formed on a gallium arsenide (GaAs) wafer. Further, when the second light emitting diode 130 and the third light emitting diode 140 emit light in a green or blue wavelength band, the second light emitting diode 130 and the third light emitting diode 140 may be formed on a sapphire wafer.

Accordingly, the first light emitting diode 120 may include a semiconductor layer having a permittivity different from that of the second light emitting diode 130 and the third light emitting diode 140. For example, a permittivity of a semiconductor layer of the second light emitting diode 130 and a permittivity of a semiconductor layer of the third light emitting diode 140 may be smaller than a permittivity of a semiconductor layer of the first light emitting diode 120.

Referring to FIGS. 8B and 8D together, for example, in the first light emitting diode 120, each of a first semiconductor layer 121 and a second semiconductor layer 123 may be a layer formed by doping n-type and p-type impurities into a material, such as aluminum gallium indium phosphide (AlGaInP), indium aluminum phosphide (InAlP), or gallium arsenide (GaAs). The p-type impurity may be magnesium, zinc (Zn), beryllium (Be), and the like, and the n-type impurity may be silicon (Si), germanium, tin (Sn), and the like, but they are not limited thereto.

In the meantime, the first light emitting diode 120 may further include an etch stop layer below the first semiconductor layer 121 to suppress a damage of the first semiconductor layer 121, but is not limited thereto.

In the first light emitting diode 120, the emission layer 122, for example, may be formed of aluminum gallium indium phosphide (AlGaInP) or indium gallium phosphide (GaInP), but is not limited thereto.

In the first light emitting diode 120, the first electrode 124 and the second electrode 125 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but are not limited thereto.

In the meantime, any one of the first electrode 124 and the second electrode 125 may include a ferromagnetic material. For example, the first electrode 124 may include a ferromagnetic material, such as nickel (Ni).

In the first light emitting diode 120, an encapsulation film 126 may be formed of an insulating material.

In the first light emitting diode 120, a pattern 127 may include one or more metal materials, among titanium dioxide (TiO₂), indium tin oxide (ITO), gold (Au), silver (Ag), aluminum (Al), and chromium (Cr).

Next, in the second light emitting diode 130, each of a first semiconductor layer 131 and a second semiconductor layer 133 may be formed of a material having a permittivity which is smaller than those of the first semiconductor layer 121 and the second semiconductor layer 123 of the first light emitting diode 120. For example, each of the first semiconductor layer 131 and the second semiconductor layer 133 of the second light emitting diode 130 may be a layer formed by doping n-type and p-type impurities into a material, such as gallium nitride (GaN), but is not limited thereto.

The emission layer 132 of the second light emitting diode 130 may be formed of a material having a permittivity smaller than that of the emission layer 122 of the first light emitting diode 120. The emission layer 132 of the first light emitting diode 130, for example, may be formed of aluminum indium gallium nitride (AlInGaN), indium gallium nitride (InGaN), or gallium nitride (GaN), but is not limited thereto.

In the second light emitting diode 130, the first electrode 134 and the second electrode 135 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but are not limited thereto.

In the meantime, any one of the first electrode 134 and the second electrode 135 may include a ferromagnetic material. For example, the first electrode 134 may include a ferromagnetic material, such as nickel (Ni).

In the second light emitting diode 130, an encapsulation film 136 may be formed of an insulating material.

In the second light emitting diode 130, a pattern 137 may include one or more metal materials, among titanium dioxide (TiO₂), indium tin oxide (ITO), gold (Au), silver (Ag), aluminum (Al), and chromium (Cr).

Next, in the third light emitting diode 140, the first semiconductor layer 141 and the second semiconductor layer 143 may be formed of a material having a permittivity which is smaller than those of the first semiconductor layer 121 and the second semiconductor layer 123 of the first light emitting diode 120. For example, each of the first semiconductor layer 141 and the second semiconductor layer 143 of the third light emitting diode 140 may be a layer formed by doping n-type and p-type impurities into a material, such as gallium nitride (GaN), but is not limited thereto.

The emission layer 142 of the third light emitting diode 140 may be formed of a material having a permittivity smaller than that of the emission layer 122 of the first light emitting diode 120. The emission layer 142 of the third light emitting diode 140, for example, may be formed of aluminum indium gallium nitride (AlInGaN), indium gallium nitride (InGaN), or gallium nitride (GaN), but is not limited thereto.

In the third light emitting diode 140, each of the first electrode 144 and the second electrode 145 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but are not limited thereto.

In the meantime, any one of the first electrode 144 and the second electrode 145 may include a ferromagnetic material. For example, the first electrode 144 may include a ferromagnetic material, such as nickel (Ni).

In the third light emitting diode 140, the encapsulation film 146 may be formed of an insulating material.

In the third light emitting diode 140, the pattern 147 may include one or more metal materials, among titanium dioxide (TiO₂), indium tin oxide (ITO), gold (Au), silver (Ag), aluminum (Al), and chromium (Cr).

Next, the assembling substrate 10 may be located above the chamber CB filled with the light emitting diode LED. The assembling substrate 10 in which the plurality of openings OLH are formed may be disposed so as to face the chamber CB.

Next, a magnet MG may be located on the assembling substrate 10. The light emitting diodes LED sinking on the bottom of the chamber CB or floating may move toward the assembling substrate 10 by a magnetic force of the magnet MG.

An upper portion of the light emitting diode LED on which the first electrode and the second electrode of the plurality of light emitting diodes LED are formed may have a step. Accordingly, the first electrode and the second electrode including a ferromagnetic material may be disposed at the upper portion of the plurality of light emitting diodes LED on which the step is formed. Therefore, if a magnitude of a magnetic field formed on the plurality of light emitting diodes LED and the magnet MG is large, the upper portion of the plurality of light emitting diodes LED having a step may be guided into the plurality of openings OLH so as to be directed to the assembly electrode AE. In this case, the influence of the electric field generated by the assembly electrode AE is small so that the plurality of light emitting diodes LED may move along with the magnet MG to be deviated from the plurality of openings OLH while the magnet MG moves on the assembling substrate 10. Accordingly, a lower portion of the plurality of light emitting diodes LED on which a flat surface having a relatively small step is disposed may be guided so as to face the plurality of openings OLH. Therefore, the lower portion of the plurality of light emitting diodes LED may be stably fixed to the plurality of openings OLH so that even though the magnet MG moves on the assembling substrate 10, the plurality of light emitting diodes LED may not be deviated from the plurality of openings OLH.

The light emitting diode LED which moves toward the assembling substrate 10 by the magnet MG may be self-assembled on the assembling substrate 10 by an electric field formed between a plurality of assembly electrodes AE.

Specifically, a voltage is applied to the plurality of assembly lines AL and the plurality of assembly electrodes AE to self-assemble the plurality of light emitting diodes LED in the opening OLH of the organic layer OL. For example, different AC voltages are applied to the plurality of first assembly lines AL1 and the plurality of first assembly electrodes AE1 and the plurality of second assembly lines AL2 and the plurality of second assembly electrodes AE2 to form an electric field. The light emitting diode LED is dielectrically polarized by the electric field to have a polarity. The dielectrically polarized light emitting diode LED may move in a specific direction or may be fixed by dielectrophoresis (DEP), that is, by an electric field. Accordingly, the plurality of light emitting diodes LED may be temporarily self-assembled in the opening OLH of the assembling substrate 10 using dielectrophoresis.

In the meantime, when the plurality of light emitting diodes LED have different permittivity, the plurality of light emitting diodes LED may be self-assembled at different voltages. For example, the plurality of first light emitting diodes 120 may be self-assembled at a first voltage and the plurality of second light emitting diodes 130 and the plurality of third light emitting diodes 140 may be self-assembled at a second voltage. For example, when a permittivity of the plurality of second light emitting diodes 130 and a permittivity of the plurality of third light emitting diodes 140 are smaller than a permittivity of the plurality of first light emitting diodes 120, the plurality of second light emitting diodes 130 and the plurality of third light emitting diodes 140 may be self-assembled at the second voltage which is higher than the first voltage. For example, the plurality of first light emitting diodes 120 may be self-assembled at the first voltage and the plurality of second light emitting diodes 130 and the plurality of third light emitting diodes 140 may be self-assembled at the second voltage which is higher than the first voltage.

First, referring to FIG. 8B, the first voltage is applied to the plurality of assembly electrodes AE to assemble the plurality of first light emitting diodes 120 on the assembling substrate 10. In this case, the plurality of second light emitting diodes 130 and the plurality of third light emitting diodes 140 have a permittivity smaller than that of the plurality of first light emitting diodes 120. Therefore, the dielectrophoresis force formed between the plurality of second light emitting diodes 130 and the plurality of third light emitting diodes 140 and the plurality of assembly electrodes AE may be smaller than the dielectrophoresis force formed between the plurality of first light emitting diodes 120 and the plurality of assembly electrodes AE. Accordingly, only the plurality of first light emitting diodes 120 may be assembled on the plurality of assembly electrodes AE to which the first voltage is applied. In this case, a space formed between the first assembly electrode AE1 and the second assembly electrode AE2 may be deviated to one side in the first opening OLH1. Accordingly, an electric field formed between the first assembly electrode AE1 and the second assembly electrode AE2 may also be deviated to one side in the first opening OLH1. Accordingly, the pattern disposed below the first light emitting diode LED is guided by the electric field formed to be biased to one side in the first opening OLH1 to be self-aligned in a direction corresponding to an area formed between the first assembly electrode AE1 and the second assembly electrode AE2.

Next, referring to FIG. 8C, the second voltage is applied to the plurality of assembly electrodes AE to assemble the plurality of second light emitting diodes 130 and the plurality of third light emitting diodes 140 on the assembling substrate 10. In this case, a relative permeability of the ferromagnetic material included in the plurality of second light emitting diodes 130 is larger than a relative permeability of the ferromagnetic material included in the plurality of third light emitting diodes 140. Therefore, the magnetic field formed between the plurality of second light emitting diodes 130 and the magnet MG may be larger than the magnetic field formed between the plurality of third light emitting diodes 140 and the magnet MG. Accordingly, a speed of the plurality of second light emitting diodes 130 moving to the assembling substrate 10 may be faster than a speed of the plurality of third light emitting diodes 140 moving to the assembling substrate 10. Therefore, the plurality of second light emitting diodes 130 may be assembled on the assembling substrate 10 before assembling the plurality of third light emitting diodes 140 on the assembling substrate 10.

In this case, the pattern disposed below the plurality of light emitting diodes LED includes a metal material so that the force of the electric field may act more strongly. Therefore, the plurality of light emitting diodes LED may be self-aligned such that the pattern disposed therebelow corresponds to an area in which the first assembly electrode AE1 and the second assembly electrode AE2 are spaced apart from each other.

Referring to FIGS. 8C and 8D together, when the plurality of light emitting diodes LED moves toward the opening OLH of the assembling substrate 10, the plurality of light emitting diodes LED may move into the third opening OLH3 without a specific directivity, like the third light emitting diode 140. However, the space formed between the first assembly electrode AE1 and the second assembly electrode AE2 is biased to one side in the third opening OLH3 so that the third light emitting diode 140 may rotate so as to allow the pattern 147 in which the dielectrophoresis force acts more strongly to be directed to one side in the third opening OLH3. Accordingly, even though the plurality of light emitting diodes LED is aligned in the plurality of openings OLH without having a directivity during the initial alignment, the plurality of light emitting diodes LED may be realigned such that the pattern disposed therebelow corresponds to the space formed between the first assembly electrode AE1 and the second assembly electrode AE2 by the dielectrophoresis force. Accordingly, the plurality of light emitting diodes LED may be self-aligned in a desired direction.

Even though in the above description, it has been described that the plurality of light emitting diodes LED are self-assembled at different voltages, the plurality of light emitting diodes LED may be self-assembled at the same voltage. Further, the plurality of light emitting diodes LED may have different planar shapes so that the plurality of light emitting diodes may be self-assembled in the plurality of openings OLH having openings corresponding to individual planar shapes. For example, the first light emitting diode 120 may have a circular planar shape as illustrated in FIG. 2 and the second light emitting diode 130 and the third light emitting diode 140 may have different oval or polygonal planar shapes. In this case, the first opening OLH1 corresponding to the first light emitting diode 120 may have a circular planar shape and the second opening OLH2 corresponding to the second light emitting diode 130 may have an oval or polygonal planar shape corresponding to the planar shape of the second light emitting diode 130. The third opening OLH3 corresponding to the third light emitting diode 140 may have an oval or polygonal planar shape corresponding to the planar shape of the third light emitting diode 140.

When the second light emitting diode 130 and the third light emitting diode 140 having an oval or polygonal planar shape are self-assembled in the second opening OLH2 and the third opening OLH3 corresponding to the planar shapes of the second light emitting diode 130 and the third light emitting diode 140 by the magnet MG, the second light emitting diode 130 and the third light emitting diode 140 may move into the second opening OLH2 and the third opening OLH3 without having a specific directivity. In this case, since the second light emitting diode 130 and the third light emitting diode 140 do not have a circular planar shape, as described above, it may be difficult for the light emitting diode LED to rotate to be realigned such that the pattern disposed therebelow corresponds to the space formed between the first assembly electrode AE1 and the second assembly electrode AE2 by the dielectrophoresis force. However, in this case, the influence of the electric field generated by the assembly electrode AE is small so that the second light emitting diode 130 and the third light emitting diode 140 move along with the magnet MG to be deviated from the plurality of openings OLH while the magnet MG moves on the assembling substrate 10. Thereafter, the light emitting diode may be self-assembled again until the pattern disposed below the light emitting diode LED corresponds to the space formed between the first assembly electrode AE1 and the second assembly electrode AE2 by the dielectrophoresis force.

After completing the self-assembling, the fluid WT may be evaporated from the assembling substrate 10. In this case, the electric field is formed between the assembly electrodes AE until the fluid WT is completely evaporated to fix the light emitting diode LED into the opening OLH. When the assembling substrate 10 is completely dried, the electric field may be removed. In this case, even after removing the electric field, the light emitting diode LED may be temporarily fixed to the assembling substrate 10 by means of Van der Waals force.

Next, referring to FIG. 8E, the plurality of light emitting diodes LED of the assembling substrate 10 are transferred onto the donor 20.

First, the assembling substrate 10 and the donor 20 are aligned such that the plurality of light emitting diodes LED faces the donor 20. After aligning the assembling substrate 10 and the donor 20, the assembling substrate 10 and the donor 20 are bonded so that the upper portion of the light emitting diode LED may be in contact with the donor 20. In this case, the donor 20 is formed of a material having adhesiveness so that upper portions of the plurality of light emitting diodes LED are bonded to the donor 20 to move from the assembling substrate 10 to the donor 20.

The donor 20 may be configured by a polymer material having viscoelasticity, for example, poly dimethyl siloxane (PDMS), poly urethane acrylate (PUA), polyethylene glycol (PEG), polymethylmethacrylate (PMMA), polystyrene (PS), epoxy resin, urethane resin, or acrylic resin, but is not limited thereto.

Next, referring to FIG. 8F, the plurality of light emitting diodes LED on the donor 20 is transferred onto the adhesive layer 116 of the display panel PN.

First, the display panel PN in which the adhesive layer 116 is formed on a substrate 110 and the donor 20 are aligned. After placing the donor 20 such that the plurality of light emitting diodes LED of the donor 20 faces the adhesive layer 116 of the display panel PN with each other, the display panel PN and the donor 20 may be aligned.

The donor 20 and the display device (specifically, the display panel PN) are bonded to transfer the light emitting diode LED on the donor 20 onto the adhesive layer 116. The plurality of light emitting diodes LED disposed on the donor 20 are disposed so as to correspond to the plurality of sub pixels SP so that all the light emitting diodes LED on the donor 20 may be transferred onto the display panel PN at one time without selectively transferring the light emitting diodes LED. The plurality of light emitting diodes LED which are transferred onto the display panel PN are attached onto the adhesive layer 116 to be temporarily fixed.

As described above, in the assembling substrate 10 according to the exemplary embodiment of the present disclosure, the length of the first assembly electrode AE1 and the length of the second assembly electrode AE2 are disposed to be different. Therefore, the electric field formed between the first assembly electrode AE1 and the second assembly electrode AE2 may be formed to be biased to one side in the opening OLH. Therefore, the light emitting diodes LED may be self-assembled so that the pattern AP disposed below the light emitting diode LED corresponds to the area formed between the first assembly electrode AE1 and the second assembly electrode AE2 by the dielectrophoresis force. Therefore, the light emitting diodes LED may be self-assembled in a desired direction regardless of the position of the first electrode E1 and the second electrode E2 of the light emitting diode LED.

The light emitting diode LED according to the exemplary embodiment of the present disclosure includes a pattern AP on a bottom surface. In this case, the pattern AP is dielectrically polarized by an electric field which is formed at an assembly electrode of an assembling substrate used for the self-assembling of the light emitting diode LED to have a polarity. The dielectrically polarized light emitting diode LED may move in a specific direction or may be fixed by dielectrophoresis (DEP), that is, by an electric field.

In the light emitting diode LED according to the exemplary embodiment of the present disclosure, the dielectrically polarized pattern AP is disposed to be biased to one side of the bottom surface of the light emitting diode LED. Therefore, the light emitting diode LED according to the exemplary embodiment of the present disclosure may change a direction in which the light emitting diode LED is disposed by adjusting a position or a shape of the assembly electrode of the assembling substrate used for the self-assembling. Accordingly, when the light emitting diode LED according to the exemplary embodiment of the present disclosure is self-assembled, the light emitting diode LED may be self-aligned in a direction intended by a user.

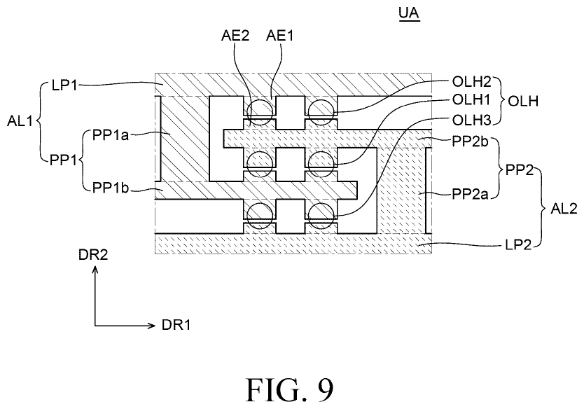

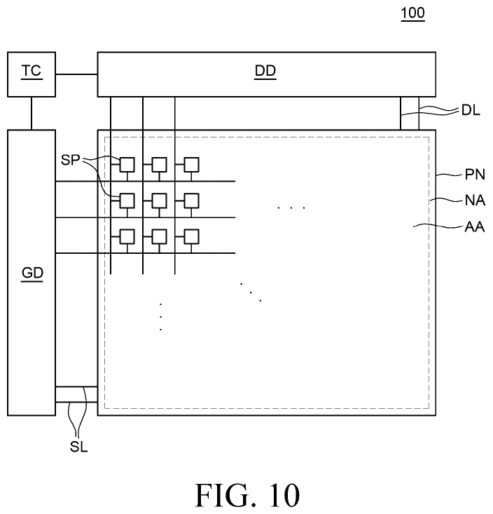

FIG. 9 is an enlarged plan view of a unit area of an assembling substrate according to another exemplary embodiment of the present disclosure.

An assembling substrate of FIG. 9 is substantially the same as the assembling substrate 10 of FIGS. 1 to 8 except for shapes of the first assembly electrode AE1 and the second assembly electrode AE2, so that a redundant description will be omitted.

Referring to FIG. 9, the first assembly electrode AE1 and the second assembly electrode AE2 may have a quadrangular planar shape. Therefore, facing surfaces of the first assembly electrode AE1 and the second assembly electrode AE2 may be parallel to each other. Therefore, the facing surfaces of the first assembly electrode AE1 and the second assembly electrode AE2 may have the same width.

The space formed between the first assembly electrode AE1 and the second assembly electrode AE2 may have a bar shape extending in one direction. For example, the space formed between the first assembly electrode AE1 and the second assembly electrode AE2 may have a bar shape extending in the first direction DR1.

A length of the first assembly electrode AE1 protruding from the first assembly line AL1 may be different from a length of the second assembly electrode AE2 protruding from the second assembly line AL2. Therefore, a size of an area of a top surface of the first assembly electrode AE1 may be different from a size of an area of a top surface of the second assembly electrode AE2. For example, the size of the area of a top surface of the first assembly electrode AE1 may be larger than the size of the area of a top surface of the second assembly electrode AE2.

As described above, in the assembling substrate according to another exemplary embodiment of the present disclosure, when the space formed between the first assembly electrode AE1 and the second assembly electrode AE2 has a bar shape, the pattern AP disposed below the light emitting diode LED to be assembled may also have a bar shape corresponding thereto. As described above, if the planar shape of the space formed between the first assembly electrode AE1 and the second assembly electrode AE2 is the same as the planar shape disposed below the light emitting diode LED, the dielectrophoresis force by the electric field formed between the first assembly electrode AE1 and the second assembly electrode AE2 may act more strongly on the pattern AP of the light emitting diode LED. Therefore, the light emitting diode LED may be more easily self-aligned on the assembling substrate 10 in a desired direction.

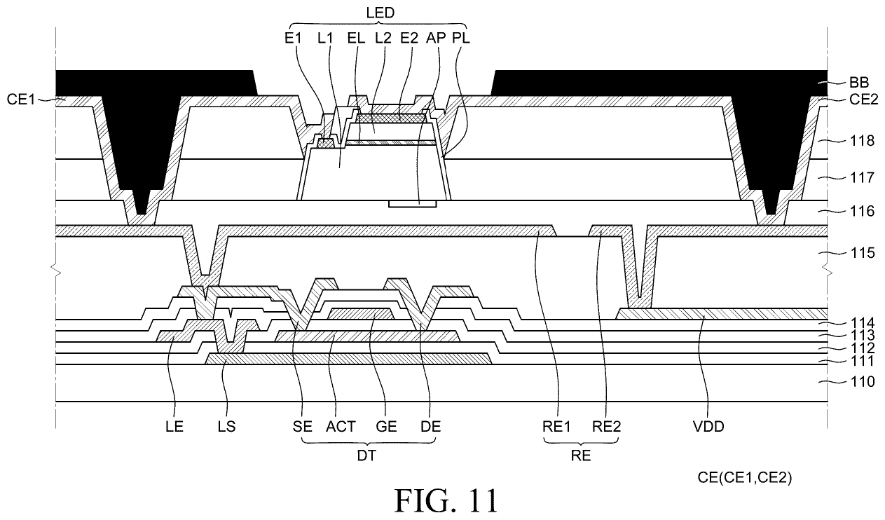

Hereinafter, a display device 100 according to the exemplary embodiment of the present disclosure will be described with reference to FIGS. 10 and 11.

FIG. 10 is a schematic diagram of a display device according to an exemplary embodiment of the present disclosure. FIG. 11 is a cross-sectional view of a sub pixel of a display device according to an exemplary embodiment of the present disclosure.

In FIG. 10, for the convenience of description, among various components of the display device 100, only a display panel PN, a gate driver GD, a data driver DD, and a timing controller TC are illustrated.

Referring to FIG. 10, the display device 100 includes a display panel PN including a plurality of sub pixels SP, a gate driver GD and a data driver DD which supply various signals to the display panel PN, and a timing controller TC which controls the gate driver GD and the data driver DD.

A driver, such as a gate driver GD, a data driver DD, and a timing controller TC, may be connected to the display panel PN in various ways. For example, the gate driver GD may be mounted in a non-active area NA in a gate in panel (GIP) manner or mounted between the plurality of sub pixels SP in an active area AA in a gate in active area (GIA) manner.

The display panel PN has a configuration which displays images to the user and includes the plurality of sub pixels SP. In the display panel PN, a plurality of scan lines SL and a plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, and a reference line.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels and a circuit for driving the plurality of sub pixels SP may be disposed. Each of the plurality of sub pixels SP is a minimum unit which configures the active area AA and n sub pixels SP may form one pixel. In each of the plurality of sub pixels SP, a light emitting diode and a thin film transistor for driving the light emitting diode may be disposed. Therefore, each of the plurality of sub pixels SP includes a light emitting diode LED and a pixel circuit to independently emit light. One pixel may include one or more first sub pixels, one or more second sub pixels, and one or more third sub pixels. In this case, the first sub pixel may be a red sub pixel, the second sub pixel may be a green sub pixel, and the third sub pixel may be a blue sub pixel, but it is not limited thereto.

The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro LED).

In the active area AA, a plurality of signal lines which transmits various signals to the plurality of sub pixels SP are disposed. For example, the plurality of signal lines may include a plurality of data lines DL which supply a data voltage to each of the plurality of sub pixels SP and a plurality of scan lines SL which supply a gate voltage to each of the plurality of sub pixels SP. The plurality of scan lines SL extend in one direction in the active area AA to be connected to the plurality of sub pixels SP and the plurality of data lines DL extend in a direction different from the one direction in the active area AA to be connected to the plurality of sub pixels SP. In addition, in the active area AA, a low potential power line and a high potential power line may be further disposed, but are not limited thereto.

In the non-active area NA, images are not displayed, but a link line which transmits a signal to the sub pixel SP of the active area AA, a pad electrode, or a driving IC, such as a gate driver IC or a data driver IC, may be disposed.

Next, referring to FIG. 11 together, in each of the plurality of sub pixels SP of the display panel PN of the display device 100 according to the exemplary embodiment of the present disclosure, a substrate 110, a buffer layer 111, a gate insulating layer 112, a first interlayer insulating layer 113, a second interlayer insulating layer 114, a first planarization layer 115, an adhesive layer 116, a second planarization layer 117, a third planarization layer 118, a bank BB, a driving transistor DT, a light emitting diode LED, a plurality of reflective electrodes RE, a plurality of connection electrodes CE, a light shielding layer LS, and an auxiliary electrode LE are disposed.

First, the substrate 110 is a component for supporting various components included in the display device 100 and may be formed of an insulating material. For example, the substrate 110 may be formed of glass or resin. Further, the substrate 110 may be configured to include a polymer or plastics or may be formed of a material having flexibility.

The light shielding layer LS is disposed in each of the plurality of sub pixels SP on the substrate 110. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current.

The buffer layer 111 is disposed on the substrate 110 and the light shielding layer LS. The buffer layer 111 may reduce permeation of moisture or impurities through the substrate 110. The buffer layer 111 may be configured by a single layer or a double layer of silicon oxide (SiOx) or silicon nitride (SiNx), but is not limited thereto. However, the buffer layer 111 may be omitted depending on a type of substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, a contact hole through which each of the source electrode SE and the drain electrode DE is connected to the active layer ACT is formed. The first interlayer insulating layer 113 and the second interlayer insulating layer 114 are insulating layers for protecting a component below the first interlayer insulating layer 113 and the second interlayer insulating layer 114 and may be configured by a single layer or a double layer of silicon oxide SiOx or silicon nitride SiNx, but are not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113 and the second interlayer insulating layer 114, that is, a plurality of insulating layers are disposed between the gate electrode GE and the source electrode SE and the drain electrode DE. However, only one insulating layer may be disposed between the gate electrode GE and the source electrode SE and the drain electrode DE, but is not limited thereto.

As illustrated in the drawings, when a plurality of insulating layers, such as the first interlayer insulating layer 113 and the second interlayer insulating layer 114, are disposed between the gate electrode GE and the source electrode SE and the drain electrode DE, an electrode may be further formed between the first interlayer insulating layer 113 and the second interlayer insulating layer 114. The additionally formed electrode may form a capacitor with the other configuration disposed below the first interlayer insulating layer 113 or above the second interlayer insulating layer 114.

An auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE and the drain electrode DE through the auxiliary electrode LE so as not to operate as a floating gate. Therefore, fluctuation of a threshold voltage of the driving transistor DT caused by the floated light shielding layer LS may be minimized. Even though in the drawing, it is illustrated that the light shielding layer LS is connected to the source electrode SE, the light shielding layer LS may also be connected to the drain electrode DE, but is not limited thereto.

The power line VDD is disposed on the second interlayer insulting layer 114. The power line VDD is electrically connected to the light emitting diode LED together with the driving transistor DT to allow the light emitting diode LED to emit light. The power line VDD may be configured by a conductive material such as copper (Cu), aluminum (Al), molybdenum (Mo), nickel (Ni), titanium (Ti), chrome (Cr), or an alloy thereof, but is not limited thereto.

The first planarization layer 115 is disposed on the driving transistor DT and the power line VDD. The first planarization layer 115 may planarize an upper portion of the substrate 110 on which the driving transistor DT is disposed. The first planarization layer 115 may be configured by a single layer or a double layer, and for example, may be formed of photoresist or an acrylic organic material, but is not limited thereto.

A plurality of reflection electrodes RE which are spaced apart from each other are disposed on the first planarization layer 115. The plurality of reflective electrodes RE may electrically connect the light emitting diode LED to the power line VDD and the driving transistor DT and serve as a reflective plate which reflects light emitted from the light emitting diode LED to the top of the light emitting diode LED. The plurality of reflective electrodes RE are formed of a conductive material having the excellent reflecting property to reflect light emitted from the light emitting diode LED toward the top of the light emitting diode LED.

The plurality of reflection electrodes RE include a first reflection electrode RE1 and a second reflection electrode RE2. The first reflective electrode RE1 may electrically connect the driving transistor DT and the light emitting diode LED. The first reflection electrode RE1 may be connected to the source electrode SE or the drain electrode DE of the driving transistor DT through a contact hole formed in the first planarization layer 115. The first reflective electrode RE1 may be electrically connected to the first electrode E1 and the first semiconductor layer L1 of the light emitting diode LED through the first connection electrode CE1 to be described below.

The second reflective electrode RE2 may electrically connect the power line VDD and the light emitting diode LED. The second reflective electrode RE2 may be connected to the power line VDD through a contact hole formed in the first planarization layer 115 and be electrically connected to a second electrode E2 and a second semiconductor layer L2 of the light emitting diode LED through a second connection electrode CE2 to be described below.

The adhesive layer 116 is disposed on the plurality of reflective electrodes RE. The adhesive layer 116 is coated on a front surface of the substrate 110 to fix the light emitting diode LED disposed on the adhesive layer 116. For example, the adhesive layer 116 may be selected from any one of adhesive polymer, epoxy resist, UV resin, polyimide, acrylate, urethane, and polydimethylsiloxane (PDMS), but is not limited thereto.

The plurality of light emitting diodes LED are disposed in each of the plurality of sub pixels SP on the adhesive layer 116. The plurality of light emitting diodes LED are elements which emit light by a current and may include light emitting diodes LED which emit red light, green light, and blue light and implement various colored light including white by a combination thereof. For example, the plurality of light emitting diodes LED may be light emitting diodes (LED) or a micro LEDs, but is not limited thereto.

The plurality of light emitting diodes LED may include a first light emitting diode 120, a second light emitting diode 130, and a third light emitting diode 140. The first light emitting diode 120 may be disposed in a first sub pixel, the second light emitting diode 130 may be disposed in a second sub pixel, and the third light emitting diode 140 may be disposed in a third sub pixel.

The first semiconductor layer L1 of the light emitting diode LED is disposed on the adhesive layer 116 and the second semiconductor layer L2 is disposed on the first semiconductor layer L1. The first electrode E1 of the light emitting diode LED may be electrically connected to the driving transistor DT and the second electrode E2 of the light emitting diode 120 may be electrically connected to the power line VDD.

The second planarization layer 117 and the third planarization layer 118 are disposed on the adhesive layer 116. The second planarization layer 117 overlaps a part of side surfaces of the plurality of light emitting diodes LED to fix and protect the plurality of light emitting diodes LED. Specifically, even though in FIG. 11, it is illustrated that an encapsulation film PL encloses all the side surfaces of the first semiconductor layer L1, a part of the side surface of the first semiconductor layer L1 may be exposed from the encapsulation film PL. The light emitting diode LED manufactured on the wafer is separated from the wafer to be transferred onto the display panel PN. However, during the process of separating the light emitting diode LED from the wafer, a part of the encapsulation film PL may be torn. For example, a part of the encapsulation film PL which is adjacent to a lower edge of the first semiconductor layer L1 of the light emitting diode LED is torn during the process of separating the light emitting diode LED from the wafer. Accordingly, a part of a lower side surface of the first semiconductor layer L1 may be exposed to the outside. However, even though the lower portion of the light emitting diode LED is exposed from the encapsulation film PL, the first connection electrode CE1 and the second connection electrode CE2 are formed after forming the second planarization layer 117 and the third planarization layer 118 which cover the side surface of the first semiconductor layer L1. Accordingly, a short-circuit defect may be minimized.

The third planarization layer 118 may include an opening area which exposes the first electrode E1 and the second electrode E2 of the light emitting diode LED. The first electrode E1 and the second electrode E2 of the light emitting diode LED are exposed from the third planarization layer 118 and the third planarization layer 118 is partially disposed in an area between the first electrode E1 and the second electrode E2 to minimize a short-circuit defect.

The second planarization layer 117 and the third planarization layer 118 may be configured by a single layer or a double layer, and for example, may be formed of photoresist or an acrylic organic material, but are not limited thereto. Even though in the present disclosure, it is described that the second planarization layer 117 and the third planarization layer 118 are disposed, the planarization layer may be formed by a single layer, but is not limited thereto.

The plurality of connection electrodes CE are disposed on the third planarization layer 118. The plurality of connection electrodes CE includes a plurality of first connection electrodes CE1 and a plurality of second connection electrodes CE2.

The first connection electrode CE1 is disposed in each of the plurality of sub pixels SP to electrically connect the light emitting diode LED and the driving transistor DT. The first connection electrode CE1 may be connected to the first reflection electrode RE1 through the contact hole formed in the third planarization layer 118, the second planarization layer 117, and the adhesive layer 116. Accordingly, the first connection electrode CE1 may be electrically connected to any one of the source electrode SE and the drain electrode DE of the driving transistor DT through the first reflective electrode RE1. The first connection electrode CE1 may be connected to the first electrodes E1 of the plurality of light emitting diodes LED through a contact hole formed in the third planarization layer 118. Accordingly, the first connection electrode CE1 may electrically connect the driving transistor DT to the first electrode E1 and the first semiconductor layer L1 of the plurality of light emitting diodes LED.

The second connection electrode CE2 may electrically connect the light emitting diode LED and the power line VDD. The second connection electrode CE2 may be connected to the second reflection electrode RE2 through the contact holes formed in the third planarization layer 118, the second planarization layer 117, and the adhesive layer 116. Accordingly, the second connection electrode CE2 may be electrically connected to the power line VDD through the second reflective electrode RE2. The second connection electrode CE2 may be connected to the second electrodes E2 of the plurality of light emitting diodes LED through a contact hole formed in the third planarization layer 118. Accordingly, the second connection electrode CE2 may electrically connect the power line VDD to the second electrode E2 and the second semiconductor layer L2 of the plurality of light emitting diodes LED.

The first connection electrode CE1 and the second connection electrode CE2 may be disposed on the same layer. However, the first connection electrode CE1 and the second connection electrode CE2 may be disposed to be spaced apart from each other on the same layer. Therefore, the first connection electrode CE1 and the second connection electrode CE2 may not be electrically connected.

The bank BB may be disposed on the third planarization layer 118. The bank BB may be disposed to be spaced apart from the light emitting diode LED with a predetermined interval.

The bank BB may be formed of an opaque material to reduce color mixture between the plurality of sub pixels SP and for example, may be formed of black resin, but is not limited thereto.

In the meantime, as the display device 100 according to the exemplary embodiment of the present disclosure, after self-assembling the plurality of light emitting diodes LED on a separate assembling substrate 10, the display device 100 may be manufactured by transferring the plurality of light emitting diodes LED self-assembled using the donor 20 onto the display panel PN from the assembling substrate 10.

The display device 100 according to the exemplary embodiment of the present disclosure may control an assembling position of the light emitting diode LED according to the difference of the dielectrophoresis force in accordance with a dielectric characteristic of the display device 100 using the assembling substrate 10 according to the exemplary embodiment of the present disclosure. Further, the display device 100 according to the exemplary embodiment of the present disclosure is manufactured using the assembling substrate 10 including the light emitting diode LED including a pattern AP biased to one side therebelow and the first assembly electrode AE1 and the second assembly electrode AE2 having different lengths. Therefore, the light emitting diodes LED may be self-aligned in a desired direction using the dielectrophoresis force concentrated on the pattern AP.

In the meantime, when the light emitting diodes are assembled having an arbitrary directivity, rather than a fixed directivity, positions of the first electrode and the second electrode of the light emitting diode may be different in each of the plurality of light emitting diodes. Therefore, it is difficult to identify the positions of the first electrode and the second electrode of all the light emitting diodes so that it may be difficult to form the first connection electrode and the second connection electrode connected to the first electrode and the second electrode, respectively, on the same layer.

Therefore, in the display device 100 according to the exemplary embodiment of the present disclosure, the light emitting diode LED is aligned in a desired direction so that the positions of the first electrode E1 and the second electrode E2 of the light emitting diode LED may be fixed in a desired direction. Therefore, the first connection electrode CE1 and the second connection electrode CE2 connected to the first electrode E1 and the second electrode E2, respectively, may be formed on the same layer. Therefore, as compared with an example that the first connection electrode CE1 and the second connection electrode CE2 are formed on different layers, the manufacturing process may be simplified.

In the display device 100 according to the exemplary embodiment of the present disclosure, an asymmetric light emitting diode LED in which the first electrode E1 and the second electrode E2 are disposed on different sides is used so that luminous efficiency may be increased.

The exemplary embodiments of the present disclosure can also be described as follows.

In one embodiment, a display device may include a substrate and a plurality of light emitting diodes disposed on the substrate. Each of the light emitting diodes may include a semiconductor stack having a first semiconductor layer L1, an emission layer EL disposed on the first semiconductor layer L1, and a second semiconductor layer L2 disposed on the emission layer EL. A pair of electrodes may be electrically connected to the semiconductor stack to provide current injection to the emission layer. Each of the light emitting diodes may further include an alignment structure AP disposed asymmetrically with respect to a center CE of the semiconductor stack (or center CE of the first semiconductor layer L1). The alignment structure (interchangeably used with ‘pattern’) may be configured to interact with an external field to generate a rotational moment that aligns the light emitting diode on the substrate. The external field may include, for example, an electric field, a magnetic field, an electromagnetic field, or any combination thereof, and may be generated to orient each light emitting diode in a uniform direction during assembly or operation of the display device.

In some embodiments, a shape of the alignment structure may be selected according to a distribution of the external field. For example, the geometry or aspect ratio of the alignment structure may be designed to correspond to the spatial characteristics or intensity distribution of the electric or magnetic field generated by assembly electrodes or magnetic sources. By selecting a suitable shape for the alignment structure, the resulting torque or force acting on the light emitting diode may be optimized to promote efficient and accurate alignment of the light emitting diode on the substrate.

In one example, the alignment structure may have a circular, rectangular, bar-shaped, or other asymmetric configuration. A bar-shaped alignment structure may produce a directional polarization or magnetization axis when subjected to a non-uniform field, thereby generating a rotational moment that orients the light emitting diode. Alternatively, a rectangular or circular configuration may be used to achieve controlled field distribution within or around the light emitting diode. The alignment structure is not limited to a particular geometry and may adopt any asymmetric configuration capable of producing orientation or alignment in response to an external field.

Differently stated, a geometry of the alignment structure may be configured to control a magnitude or direction of the rotational moment acting on the light emitting diode. The relative dimensions, curvature, or orientation of the alignment structure may be adjusted to vary the effective torque produced when the light emitting diode interacts with the external field. For example, an elongated alignment structure may generate a stronger or more directional moment compared to a symmetric shape, allowing controlled rotation of the light emitting diode into a predetermined orientation on the substrate.

In certain embodiments, the semiconductor stack may have a first surface FS (see FIG. 1), and the alignment structure may be disposed to contact or adhere to the first surface FS of the semiconductor stack. The alignment structure may be formed directly beneath the first semiconductor layer L1 or on a surface opposite to the emission layer. Physical contact between the alignment structure and the semiconductor stack may facilitate electrical, thermal, or mechanical coupling and allow effective interaction with external fields applied during the assembly process.

In one embodiment, the pair of electrodes may include a first electrode E1 and a second electrode E2, with the emission layer EL of the semiconductor stack positioned between the first electrode E1 and the second electrode E2. At least one of the first electrode or the second electrode may not overlap with the alignment structure in a plan view, thereby ensuring that the field-responsive behavior of the alignment structure is not shielded or interfered with by the electrodes. This configuration allows the alignment structure to respond effectively to an applied external field while maintaining proper electrical contact for light emission.

In some embodiments, a size of the second electrode E2 may be greater than a size of the alignment structure AP such that, when viewed in plan view, the second electrode fully overlaps the alignment structure (see FIG. 2). This arrangement may provide complete coverage of the alignment structure for protection, charge uniformity, or optical control while maintaining the structural asymmetry necessary to produce the desired alignment torque.

In other embodiments, the second electrode E2 and the alignment structure AP may differ in size such that, when seen in a plan view, the second electrode E2 only partially overlaps the alignment structure AP (see FIG. 3). Partial overlap may be used to adjust the effective interaction region between the external field and the alignment structure, thereby modifying the resulting rotational moment or alignment behavior. This configuration may allow finer control over the self-alignment characteristics of the light emitting diodes during assembly.

In one embodiment, an assembling substrate may include a substrate, a first assembly line disposed on the substrate, a second assembly line disposed on the substrate, and an organic layer having an opening corresponding to a position for receiving a light emitting diode. A first assembly electrode may protrude from one side of the first assembly line, and a second assembly electrode may protrude from one side of the second assembly line so as to face the first assembly electrode. A length of the first assembly electrode that protrudes from the first assembly line may differ from a length of the second assembly electrode that protrudes from the second assembly line. This difference in length may generate an asymmetric electric field between the first and second assembly electrodes when a voltage is applied. The asymmetric electric field may be configured to align the light emitting diode placed in the opening by inducing a rotational moment or translational movement that orients the light emitting diode in a desired direction during assembly.

The exemplary embodiments of the present disclosure can further be described as follows.

A light emitting diode according to an aspect of the present disclosure comprises a first semiconductor layer, a first electrode disposed on the first semiconductor layer, an emission layer disposed on the first semiconductor layer, a second semiconductor layer disposed on the emission layer, a second electrode disposed on the second semiconductor layer and a pattern which is disposed below the first semiconductor layer and is disposed at one side with respect to a center of the first semiconductor layer.

The pattern or the alignment structure may have a circular shape or a rectangular shape. In particular, the shape of the alignment structure may be selected according to the distribution of the external electric or magnetic field. For example, the alignment structure may have a circular, rectangular, or bar-shaped configuration, or another asymmetric form. The geometry of the alignment structure affects the induced polarization or magnetization and thereby the magnitude and direction of the rotational moment acting on the light emitting diode. By matching the shape and orientation of the alignment structure to the field pattern generated by the assembly electrodes, stable and accurate self-alignment of the light emitting diodes on the substrate can be achieved.

The first electrode may have an oval shape extending in one direction, the pattern may have a rectangular shape, and a major axis of the first electrode and a long side of the pattern may be parallel to each other.

The pattern may include one or more of titanium dioxide (TiO₂), indium tin oxide (ITO), gold (Au), silver (Ag), aluminum (Al), and chromium (Cr).

The first electrode may be disposed at the other side with respect to the center of the first semiconductor layer and the second electrode may be disposed at the one side with respect to the center of the first semiconductor layer.

The pattern may overlap the second electrode and the emission layer and may do not overlap the first electrode.

An assembling substrate according to an aspect of the present disclosure comprises a substrate, a first assembly line disposed on the substrate, a first assembly electrode which protrudes from one side of the first assembly line, a second assembly line disposed on the substrate, a second assembly electrode which protrudes from one side of the second assembly line and is disposed so as to face the first assembly electrode, and an organic layer which is disposed on the substrate and includes an opening, wherein a length of the first assembly electrode which protrudes from one side of the first assembly line is different from a length of the second assembly electrode which protrudes from one side of the second assembly line.

Each of the first assembly electrode and the second assembly electrode may include a part which may be narrowed toward an end thereof.

An end of the first assembly electrode and an end of the second assembly electrode may face each other.

The first assembly electrode and the second assembly electrode may have a quadrangular planar shape and an area of a top surface of the first assembly electrode may be larger than an area of a top surface of the second assembly electrode.

A space formed between the first assembly electrode and the second assembly electrode may have a bar shape extending in one direction.

A space formed between the first assembly electrode and the second assembly electrode may be disposed at one side with respect to a center of the opening.

An overlapping area of the first assembly electrode and the opening may be larger than an overlapping area of the second assembly electrode and the opening.

A display device according to as aspect of the present disclosure comprises, a substrate, and a light emitting diode disposed on the substrate, wherein the light emitting diode includes, a first semiconductor layer, a first electrode disposed on the first semiconductor layer, an emission layer disposed on the first semiconductor layer, a second semiconductor layer disposed on the emission layer, a second electrode disposed on the second semiconductor layer, and a pattern disposed below the first semiconductor layer and is disposed at one side with respect to a center of the first semiconductor layer.

A planar shape of the pattern may be a circle or a rectangle.

The pattern may overlap the second electrode.

The display device may further comprise a transistor and a power line disposed between the substrate and the light emitting diode, a planarization layer which may be disposed on the transistor and the power line so as to enclose the light emitting diode and includes a plurality of contact holes, a first connection line which may be disposed on the planarization layer and electrically connects the first electrode and the transistor through a part of the plurality of contact holes, and a second connection line which may be disposed on the planarization layer and electrically connects the second electrode and the power line through the other part of the plurality of contact holes.

The first connection line and the second connection line may be disposed on the same layer and may include the same material.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting diode, comprising:
a first semiconductor layer;
a first electrode disposed on the first semiconductor layer;
an emission layer disposed on the first semiconductor layer;
a second semiconductor layer disposed on the emission layer;
a second electrode disposed on the second semiconductor layer; and
a pattern which is disposed below the first semiconductor layer and is disposed at one side with respect to a center of the first semiconductor layer.

2. The light emitting diode according to claim 1, wherein the pattern has a circular shape or a rectangular shape.

3. The light emitting diode according to claim 2, wherein the first electrode has an oval shape extending in one direction, the pattern has a rectangular shape, and a major axis of the first electrode and a long side of the pattern are parallel to each other.

4. The light emitting diode according to claim 1, wherein the pattern includes one or more of titanium dioxide, indium tin oxide, gold, silver, aluminum, and chromium.

5. The light emitting diode according to claim 1, wherein the first electrode is disposed at the other side with respect to the center of the first semiconductor layer and the second electrode is disposed at the one side with respect to the center of the first semiconductor layer.

6. The light emitting diode according to claim 5, wherein, in a plan view, the pattern overlaps the second electrode and the emission layer and does not overlap the first electrode.

7. An assembling substrate for assembling a plurality of light emitting diodes, comprising:
a substrate;
a first assembly line disposed on the substrate;
a first assembly electrode protruding from one side of the first assembly line;
a second assembly line disposed on the substrate;
a second assembly electrode protruding from one side of the second assembly line and facing the first assembly electrode; and
an organic layer disposed on the substrate and having an opening,
wherein a length of the first assembly electrode that protrudes from one side of the first assembly line is different from a length of the second assembly electrode that protrudes from one side of the second assembly line.

8. The assembling substrate according to claim 7, wherein each of the first assembly electrode and the second assembly electrode includes a part which is narrowed toward an end thereof.

9. The assembling substrate according to claim 8, wherein an end of the first assembly electrode and an end of the second assembly electrode face each other.

10. The assembling substrate according to claim 7, wherein the first assembly electrode and the second assembly electrode have a quadrangular planar shape and an area of a top surface of the first assembly electrode is larger than an area of a top surface of the second assembly electrode.

11. The assembling substrate according to claim 10, wherein a space formed between the first assembly electrode and the second assembly electrode has a bar shape extending in one direction.

12. The assembling substrate according to claim 7, wherein a space formed between the first assembly electrode and the second assembly electrode is disposed at one side with respect to a center of the opening.

13. The assembling substrate according to claim 7, wherein an overlapping area of the first assembly electrode and the opening is larger than an overlapping area of the second assembly electrode and the opening.

14. A display device, comprising:
a substrate; and
a light emitting diode disposed on the substrate,
wherein the light emitting diode includes:
a first semiconductor layer;
a first electrode disposed on the first semiconductor layer;
an emission layer disposed on the first semiconductor layer;
a second semiconductor layer disposed on the emission layer;
a second electrode disposed on the second semiconductor layer; and
a pattern disposed below the first semiconductor layer and is disposed at one side with respect to a center of the first semiconductor layer.

15. The display device according to claim 14, wherein a planar shape of the pattern is a circle or a rectangle.

16. The display device according to claim 14, wherein the pattern overlaps the second electrode.

17. The display device according to claim 14, further comprising:
a transistor and a power line disposed between the substrate and the light emitting diode;
a planarization layer which is disposed on the transistor and the power line so as to enclose the light emitting diode and includes a plurality of contact holes;
a first connection line which is disposed on the planarization layer and electrically connects the first electrode and the transistor through a part of the plurality of contact holes; and
a second connection line which is disposed on the planarization layer and electrically connects the second electrode and the power line through the other part of the plurality of contact holes.

18. The display device according to claim 17, wherein the first connection line and the second connection line are disposed on the same layer and include the same material.

19. A display device, comprising:
a substrate; and
a plurality of light emitting diodes disposed on the substrate, each of the light emitting diodes including:
a semiconductor stack including a first semiconductor layer, an emission layer, and a second semiconductor layer;
a pair of electrodes electrically connected to the semiconductor stack; and
an alignment structure disposed asymmetrically with respect to a center of the semiconductor stack, the alignment structure being configured to interact with an external field to generate a rotational moment that aligns the light emitting diode on the substrate.

20. The display device of claim 19, wherein a shape of the alignment structure is selected according to a distribution of the external field.

21. The display device of claim 19, wherein the alignment structure has a circular, rectangular, bar-shaped, or other asymmetric configuration.

22. The display device of claim 19, wherein the semiconductor stack has a first surface and the alignment structure contacts the first surface of the semiconductor stack.

23. The display device of claim 19, wherein the pair of electrodes includes a first electrode and a second electrode, the emission layer of the semiconductor stack being between the first electrode and the second electrode, and
wherein at least one of the first electrode or the second electrode does not overlap with the alignment structure in a plan view.

24. The display device of claim 23, wherein a size of the second electrode is bigger than a size of the alignment structure such that when seen in a plan view, the second electrode fully overlaps the alignment structure.

25. The display device of claim 23, wherein the second electrode and the alignment structure differ in size such that when seen in a plan view, the second electrode only partially overlaps the alignment structure.

26. The assembling substrate according to claim 7, wherein the opening corresponds to a position for receiving a light emitting diode, and
wherein the length of the first assembly electrode that protrudes from the first assembly line is different from the length of the second assembly electrode that protrudes from the second assembly line, such that an asymmetric electric field is generated between the first and second assembly electrodes when a voltage is applied, the asymmetric electric field being configured to align the light emitting diode placed in the opening.
